(19) United States
(12) Patent Application Publication
(10) Pub. No.: US 2026/0060126 A1
(43) Pub. Date: Feb. 26, 2026

(54) SEMICONDUCTOR DEVICE AND METHOD FOR MANUFACTURING SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Daisuke Koike, Tama Tokyo (JP)

(21) Appl. No.: 19/372,753

(22) Filed: Oct. 29, 2025

Related U.S. Application Data
(63) Continuation of application No. PCT/JP2024/006541, filed on Feb. 22, 2024.

(30) Foreign Application Priority Data
Jul. 31, 2023 (JP) 2023-124814

(51) Int. Cl. H01L 23/00

(52) U.S. Cl. CPC H01L 24/29; H01L 24/27; H01L 24/32; H01L 2224/2732; H01L 2224/27848; H01L 2224/2929; H01L 2224/29499; H01L 2224/32225

(57) ABSTRACT

A semiconductor device according to an embodiment includes a semiconductor chip, a substrate, and an adhesive layer. The substrate supports the semiconductor chip. The adhesive layer is disposed between the semiconductor chip and the substrate. The adhesive layer bonds the semiconductor chip and the substrate. The adhesive layer has a first portion and a plurality of second portions. The first portion is formed of a first material. The plurality of second portions are formed of a second material. The second material has a greater elastic modulus and a greater thermal conductivity than the first material. The second portions are located inside the first portion. Each of the second portions is in contact with and connects the semiconductor chip and the substrate.

### CROSS-REFERENCE TO RELATED APPLICATION

This application is based upon and claims the benefit of priority from Japanese Patent Application No. 2023-124814, filed Jul. 31, 2023, the entire contents of which are incorporated herein by reference.

### FIELD

Embodiments described herein relate generally to a semiconductor device and a method for manufacturing a semiconductor device.

### BACKGROUND

In a semiconductor device in which a semiconductor chip is mounted on a substrate such as a lead frame, the semiconductor chip and the substrate are bonded via an adhesive such as a die attachment material. In order to realize the characteristics of a semiconductor chip, it is necessary to efficiently dissipate heat generated during an operation. Thus, the adhesive is formed by blending a highly heat-conductive material, such as silver filler, which has high thermal conductivity, into a resin material, such as an epoxy resin or an acrylic resin.

The heat dissipation properties of the semiconductor chip during the operation of the semiconductor chip are improved by increasing a proportion of the highly heat-conductive material in the adhesive. The substrate expands due to heat transmitted from the semiconductor chip, but since the resin material in the adhesive has a low elastic modulus, the adhesive can expand in accordance with the expansion of the substrate. In the adhesive, when the proportion of the resin material with a low elastic modulus decreases and the proportion of the highly heat-conductive material with a high elastic modulus increases, it becomes difficult for the adhesive to expand in accordance with the expansion of the substrate. In this case, the adhesive may peel off due to stress caused by moisture absorption reflow or a temperature cycle test. When the adhesive peels off and an air layer is formed on a surface of the substrate, thermal conductivity may be reduced.

### BRIEF DESCRIPTION OF THE DRAWINGS

FIG. 1 is a cross-sectional view showing a semiconductor device of a first embodiment.

FIG. 2 is a plan view showing the semiconductor device of the first embodiment.

FIG. 3 is a diagram showing steps of a method for manufacturing the semiconductor device in the first embodiment.

FIG. 4 is a diagram showing steps of the method for manufacturing the semiconductor device in the first embodiment.

FIG. 5 is a diagram showing steps of the method for manufacturing the semiconductor device in the first embodiment.

FIG. 6 is a diagram showing steps of the method for manufacturing the semiconductor device in the first embodiment.

FIG. 7 is a diagram showing steps of the method for manufacturing the semiconductor device in the first embodiment.

FIG. 8 is a diagram showing steps of the method for manufacturing the semiconductor device in the first embodiment.

FIG. 9 is a diagram showing steps of the method for manufacturing the semiconductor device in the first embodiment.

FIG. 10 is a diagram showing steps of the method for manufacturing the semiconductor device in the first embodiment.

FIG. 11 is a plan view showing a semiconductor device of a second embodiment.

FIG. 12 is a plan view showing a semiconductor device of a third embodiment.

### DETAILED DESCRIPTION

According to an embodiment, a semiconductor device includes a semiconductor chip, a substrate, and an adhesive layer. The substrate supports the semiconductor chip. The adhesive layer is disposed between the semiconductor chip and the substrate. The adhesive layer bonds the semiconductor chip and the substrate. The adhesive layer has a first portion and a plurality of second portions. The first portion is formed of a first material. The plurality of second portions are formed of a second material. The second material has a greater elastic modulus and a greater thermal conductivity than the first material. The plurality of second portions are located inside the first portion. Each of the plurality of second portions is in contact with and connects the semiconductor chip and the substrate.

Hereinafter, a semiconductor device and a method for manufacturing a semiconductor device according to an embodiment will be described with reference to the drawings.

In the following description, components having the same or similar functions are designated by the same reference numerals, and duplicate descriptions thereof may be omitted.

### First Embodiment

A configuration of a semiconductor device in a first embodiment will be described below.

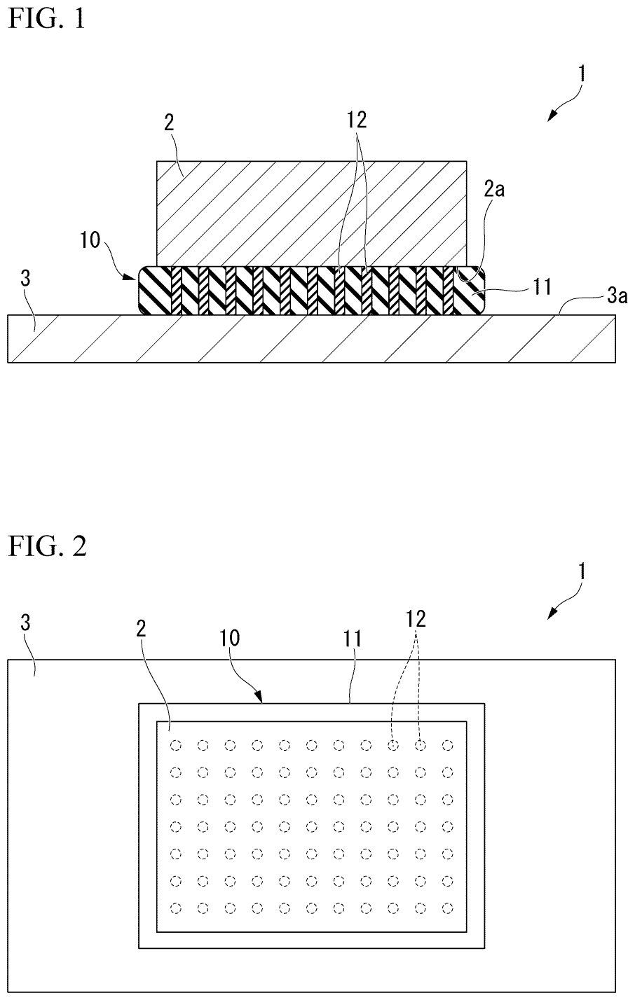

FIG. 1 is a cross-sectional view of the semiconductor device 1.

As shown in FIG. 1, the semiconductor device 1 includes a semiconductor chip 2, a substrate 3, and an adhesive layer 10. The substrate 3 is, for example, a lead frame that is electrically connected to the semiconductor chip 2 by wire bonding. In the following description, the substrate 3 will be referred to as a lead frame 3.

The lead frame 3 supports the semiconductor chip 2. The lead frame 3 is made of, for example, copper.

In the following description, a direction in which the semiconductor chip 2, the adhesive layer 10, and the substrate 3 are laminated and arranged is referred to as an up-down direction. The side in the up-down direction on which the semiconductor chip 2 is disposed is referred to as the “upper side. ” The side in the up-down direction on which the lead frame 3 is disposed is referred to as the “lower side. ” A direction perpendicular to the up-down direction is referred to as a horizontal direction. In the horizontal direction, the sides are referred to as the “left side”and the “right side”as appropriate.

The terms “upper side,” “lower side,” “left side,” and “right side” are merely names used to describe a relative positional relationship of each part, and an actual arrangement relationship may be an arrangement relationship other than the arrangement relationship indicated by the names.

The adhesive layer 10 is disposed between the semiconductor chip 2 and the lead frame 3. The adhesive layer 10 bonds the semiconductor chip 2 to the lead frame 3. The adhesive layer 10 is, for example, a die attachment material. The adhesive layer 10 has a first portion 11 and a second portion 12. The first portion 11 is formed of a first material. The first material has a low elastic modulus and a low thermal conductivity. Examples of the first material include an epoxy resin and an acrylic resin.

FIG. 2 is a plan view of the semiconductor device 1.

As shown in FIG. 2, the adhesive layer 10 is formed over a region larger than the semiconductor chip 2 in the horizontal direction. The first portion 11 of the adhesive layer 10 is formed over a region larger than the semiconductor chip 2 in the horizontal direction.

The second portion 12 is located inside the first portion 11. A plurality of second portions 12 are provided. In plan view, a plurality of columns in which the second portions 12 are disposed at intervals in a longitudinal direction are disposed at intervals in the horizontal direction. In the embodiment, longitudinal positions of the second portions 12 in the columns laterally adjacent to each other are the same. That is, the second portions 12 are disposed in a lattice pattern in plan view when seen in a direction in which the semiconductor chips 2 and the lead frames 3 are arranged.

Each of the second portions 12 is in contact with the semiconductor chip 2 and the lead frame 3. The second portions 12 are in contact with a lower surface 2a of the semiconductor chip 2 from below. The second portions 12 are in contact with an upper surface 3a of the lead frame 3 from above. Each of the second portions 12 connects the semiconductor chip 2 and the lead frame 3.

The second portions 12 are formed of a second material. The second material has a higher elastic modulus and a higher thermal conductivity than the first material.

Examples of the second material may include a metal having a high thermal conductivity, a ceramic-based material such as aluminum nitride, and the like. The second material in the embodiment includes metal particles. By including metal particles in the second material, heat can be dissipated efficiently from the semiconductor chip 2 to the lead frame 3.

The metal with a high thermal conductivity is not particularly limited, and examples thereof include gold, silver, copper, aluminum, and the like. The second material of the embodiment contains silver nanoparticles having a size of several nm to several thousand nm. The second portion 12 is formed by heating and curing the second material which is a binder paste containing silver nanoparticles.

Each of the plurality of second portions 12 has a columnar shape that extends in the up-down direction and connects the semiconductor chip 2 and the lead frame 3. Since the second portion 12 has a columnar shape that extends in the up-down direction and connects the semiconductor chip 2 and the lead frame 3, the semiconductor chip 2 and the lead frame 3 can be connected with a shortest distance. Each of the plurality of second portions 12 connects the semiconductor chip 2 and the lead frame 3 with the shortest distance, and thus heat dissipation from the semiconductor chip 2 to the lead frame 3 via the plurality of second portions 12 is improved.

In the semiconductor device 1 of the embodiment, since heat dissipation from the semiconductor chip 2 to the lead frame 3 is improved, a proportion of the second portion 12 in the adhesive layer 10 can be reduced. Since the ratio of the second portion 12 in the adhesive layer 10 can be reduced, a ratio of the first portion 11 formed of the first material having a smaller elastic modulus than the second portion 12 can be increased. In the semiconductor device 1 of the embodiment, since the proportion of the first portion 11 in the adhesive layer 10 can be increased, the adhesive layer 10 can expand in accordance with expansion of the lead frame 3 which expands due to heat transmitted from the semiconductor chip.

Each of the plurality of second portions 12 has a cylindrical shape with a circular cross section. Since each of the plurality of second portions 12 has a cylindrical shape with the circular cross section, when the first material is applied around the plurality of second portions 12 to form the first portions 11, fluidity of the first material can be improved compared to, for example, when each of the second portions 12 has a prismatic shape with a rectangular cross section.

Preferably, each of the plurality of second portions 12 has a diameter of 100 μm or more, and 200 μm or more.

When the diameter of each of the plurality of second portions 12 is less than 100 μm, a strength when the semiconductor chip 2 is mounted and a bending strength when the first material is applied around the second portions 12 may be insufficient.

Furthermore, when the diameter of each of the plurality of second portions 12 is less than 100 μm, a cross-sectional area thereof is small, which may result in insufficient heat dissipation from the semiconductor chip 2 to the lead frame 3.

When the diameter of each of the plurality of second portions 12 exceeds 200 μm, there is a possibility that the expansion of the first portion 11 in accordance with the expansion of the lead frame 3 due to heat transmitted from the semiconductor chip may be hindered.

By setting the diameter of each of the plurality of second portions 12 to 100 μm or more and 200 μm or more, it is possible to ensure the strength when the semiconductor chip 2 is mounted, the bending strength when the first material is applied around the second portions 12, the heat dissipation from the semiconductor chip 2 to the lead frame 3, and the expansion of the first portions 11 in accordance with the expansion of the lead frame 3.

A total area of the plurality of second portions 12 in contact with the semiconductor chip 2 is preferably ⅛ or more and ¼ or less of an area of a surface of the semiconductor chip 2 that faces the adhesive layer 10.

When the total area of the second portions 12 is less than ⅛ of the area of the surface of the semiconductor chip 2 that faces the adhesive layer 10, there is a possibility that the heat dissipation from the semiconductor chip 2 to the lead frame 3 may be insufficient.

When the total area of the second portions 12 exceeds ¼ of the area of the surface of the semiconductor chip 2 that faces the adhesive layer 10, there is a possibility that the expansion of the first portions 11 in accordance with the expansion of the lead frame 3 due to heat transmitted from the semiconductor chip may be hindered.

By setting the total area of the second portions 12 to ⅛ or more and ¼ or less of the area of the surface of the semiconductor chip 2 that faces the adhesive layer 10, it is possible to ensure the heat dissipation from the semiconductor chip 2 to the lead frame 3 and the expansion of the first portions 11 in accordance with the expansion of the lead frame 3.

When the total area of the second portions 12 is the same as the area of the surface of the semiconductor chip 2 that faces the adhesive layer 10, the thermal conductivity is 429 W/m·K. A desired thermal conductivity is about 50 W/m·K to 100 W/m·K.

By setting the total area of the plurality of second portions 12 in contact with the semiconductor chip 2 to ⅛ or more or ¼ or less of the area of the surface of the semiconductor chip 2 that faces the adhesive layer 10, it becomes possible to ensure the desired thermal conductivity of 50 W/m·K to 100 W/m·K.

In the semiconductor device 1 of the embodiment, since the second portions 12 directly connect the semiconductor chip 2 and the lead frame 3, heat dissipation is improved. In the semiconductor device 1 of the embodiment, since the first portion 11 having a small elastic modulus is disposed around the second portions 12, stress caused by a difference in a linear expansion coefficient between the semiconductor chip 2 and the lead frame 3 during moisture absorption/reflow and temperature cycle tests can be absorbed, and peeling can be curbed.

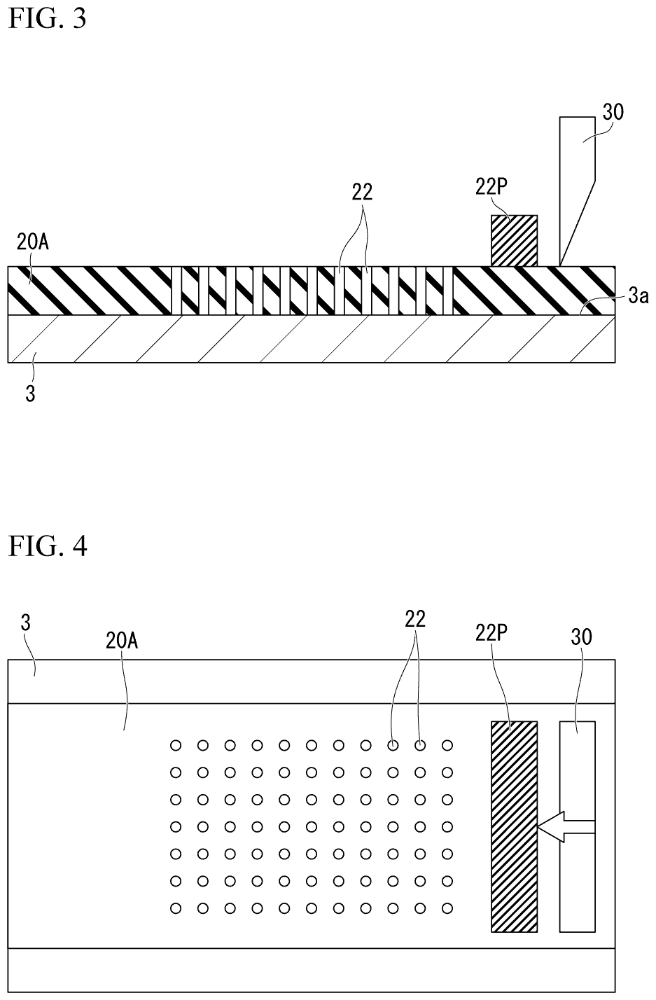

Next, a method for manufacturing the above-described semiconductor device 1 will be described with reference to FIGS. 3 to 10. FIGS. 3 to 10 are diagrams showing steps of the method for manufacturing the semiconductor device 1 in the first embodiment.

The method for manufacturing the semiconductor device 1 includes forming an adhesive layer 10 on a lead frame 3, the adhesive layer 10 having a first portion 11 formed of a first material and a plurality of second portions 12 formed of a second material having a higher elastic modulus and a higher thermal conductivity than the first material, and mounting a semiconductor chip 2 on the side of the adhesive layer 10 opposite to the lead frame 3. The forming of the adhesive layer 10 includes applying the second material onto the lead frame 3 to form a plurality of second portions 12 in contact with the lead frame 3, and applying the first material onto the lead frame 3 to form the first portion 11 in which the plurality of second portions 12 located and which is in contact with the lead frame 3. The mounting of the semiconductor chip 2 includes bringing the semiconductor chip 2 into contact with the first portion 11 and the second portion 12 and connecting the semiconductor chip 2 to the lead frame 3 via the first portion 11 and the second portion 12.

In the method for manufacturing the semiconductor device 1 of the embodiment, there is no particular limitation on a method for forming the adhesive layer 10. In the embodiment, a procedure for forming the adhesive layer 10 by sequentially forming the second portion 12 and the first portion 11 by screen printing will be described.

In the forming of the adhesive layer 10, as shown in FIG. 3, the forming of the second portion 12 by screen printing includes placing a first screen plate 20A on an upper surface 3a of the lead frame 3, molding the second portion 12 using the first screen plate 20A, and semi-curing the molded second portion 12.

The first screen plate 20A has a first screen hole 22 for forming the second portion 12. The thickness of the first screen plate 20A is the same as a length of the second portion 12 in the up-down direction. The first screen hole 22 extends in the up-down direction and has a circular cross-sectional shape. An inner diameter of the first screen hole 22 is the same as an outer diameter of the second portion 12. As shown in FIG. 4, the first screen holes 22 are disposed in a lattice pattern to correspond to positions and sizes of the second portions 12.

When the second portion 12 is formed by screen printing, first, a paste-like second material 22P is supplied to, for example, the right side with respect to the first screen hole 22 on the upper surface of the first screen plate 20A.

Next, a squeegee 30 is moved from the right side of the second material 22P to the left along the upper surface of the first screen plate 20A. Thus, the paste-like second material 22P extruded by the squeegee 30 is inserted successively from the first screen hole 22 located at a right end portion to the first screen hole 22 located at a left end portion, and shaped.

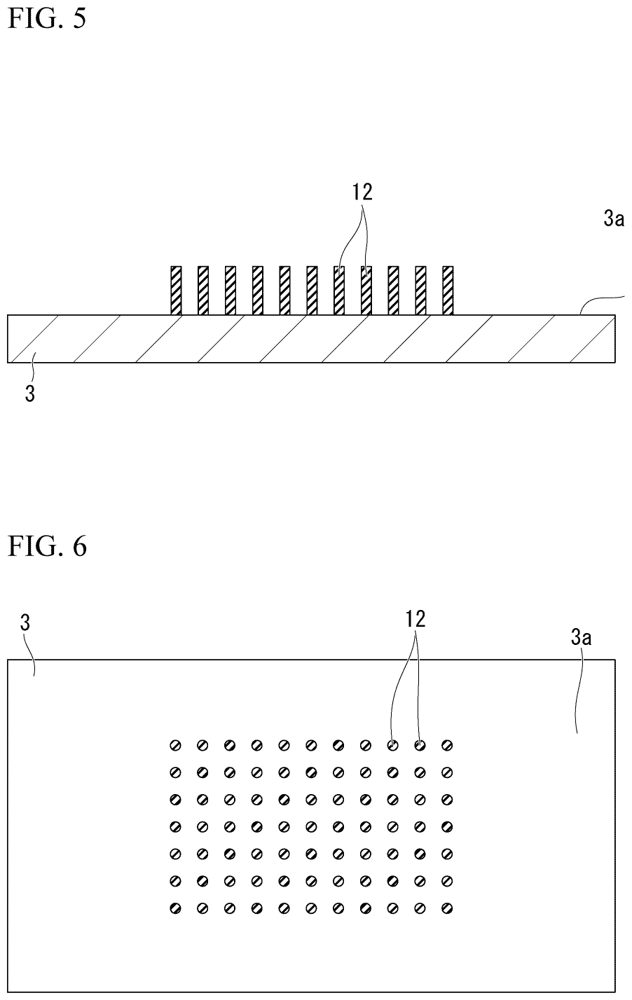

Then, by removing the first screen plate 20A from the lead frame 3, the lead frame 3 is obtained in which the plurality of second portions 12, each formed into a cylindrical shape with a lower end in contact with the upper surface 3a of the lead frame 3 and extending upward, are disposed in a lattice pattern, as shown in FIGS. 5 and 6.

The second portion 12 formed by screen printing is subjected to a semi-curing process. In the semi-curing process, the lead frame 3 on which the second portion 12 is formed is heated to 100° C. in an oven, for example. By performing the semi-curing process on the second portion 12, it is possible to curb occurrence of deformation or the like when the first portion 11 is subsequently formed.

Furthermore, in a case in which the second portion 12 formed by screen printing is completely cured, when the semiconductor chip 2 is mounted on the second portion 12 in a later process, and a flatness of an upper surface of the second portion 12 is low, there is a possibility that the second portion 12 may not be sufficiently in contact with the semiconductor chip 2 and may not be bonded sufficiently. Therefore, the second portion 12 is semi-cured so that the upper surface of the second portion 12 conforms to the semiconductor chip 2 when the semiconductor chip 2 is mounted on the second portion 12.

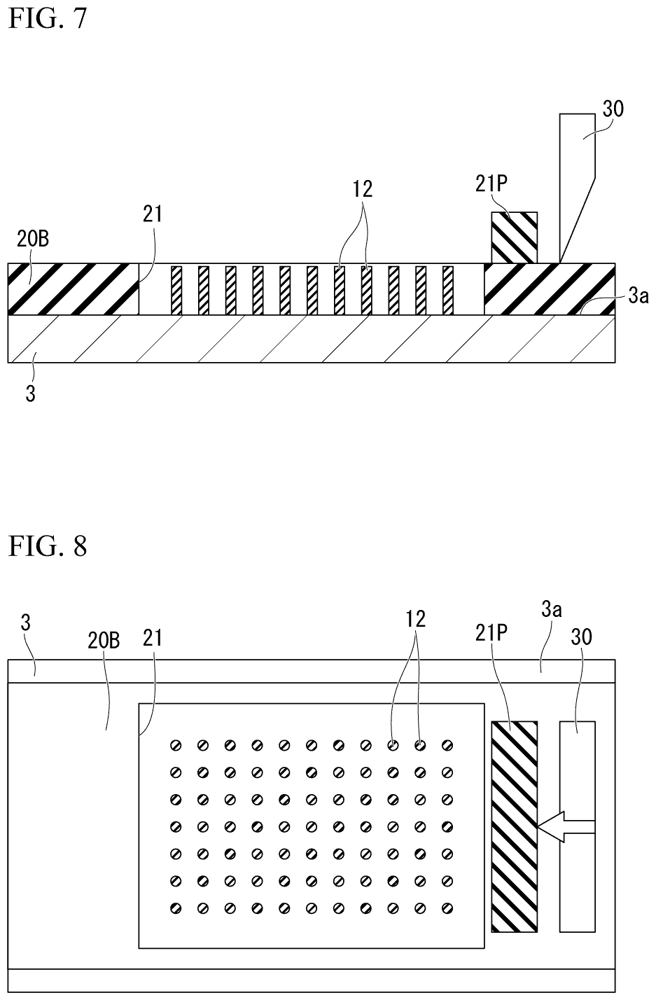

Next, in the forming of the adhesive layer 10, the forming of the first portion 11 by screen printing includes placing a second screen plate 20B on the upper surface 3a of the lead frame 3, and molding the first portion 11 using the second screen plate 20B, as shown in FIG. 7.

The second screen plate 20B has a second screen hole 21 for forming the first portion 11. The thickness of the second screen plate 20B is slightly larger than a length of the second portion 12 in the up-down direction. Since the thickness of the second screen plate 20B is slightly larger than the length of the second portion 12 in the up-down direction, it is possible to prevent the squeegee 30 from interfering with the second portion 12 when the squeegee 30 is moved along the upper surface of the second screen plate 20B. The second screen hole 21 extends in the up-down direction and has a rectangular cross-sectional shape as shown in FIG. 8. The size of an inner circumferential surface of the second screen hole 21 is the same as the size of an outer circumferential surface of the first portion 11.

When the first portion 11 is formed by screen printing, first, a paste-like first material 21P is supplied to, for example, the right side with respect to the second screen hole 21 on the upper surface of the second screen plate 20B.

Next, the squeegee 30 is moved from the right side of the first material 21P to the left along the upper surface of the second screen plate 20B. Thus, the paste-like first material 21P extruded by the squeegee 30 is inserted successively from a right end portion to a left end portion of the second screen hole 21, and shaped.

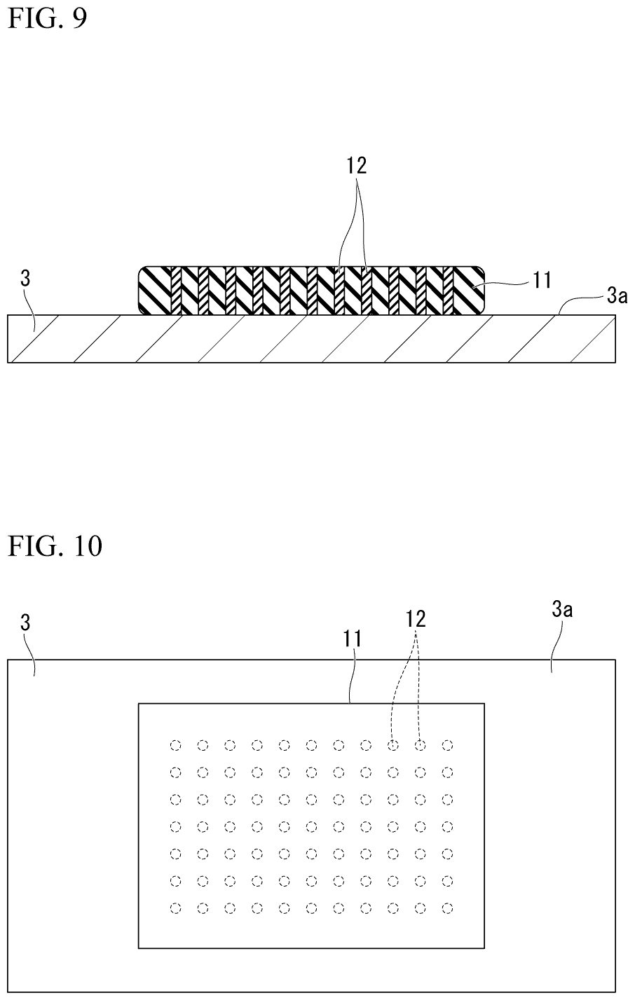

Then, by removing the second screen plate 20B from the lead frame 3, the lead frame 3 is obtained in which the first portion 11 in which the second portion 12 is located and which is formed of the first material is disposed on the upper surface 3a, as shown in FIGS. 9 and 10.

In the method for manufacturing the semiconductor device 1, the semiconductor chip 2 is mounted in contact with the first portion 11 and the second portion 12 formed by screen printing, as shown in FIG. 1. When the semiconductor chip 2 is mounted on the first portion 11 and the second portion 12, the semiconductor chip 2 is pressed with a force of, for example, about 1 N to 10 N.

As shown in FIG. 9, since the thickness of the second screen plate 20B is slightly greater than the length of the first portion 11, a thin film portion of the first portion 11 is present above the second portion 12.

Here, the first portion 11 is in an uncured state, and the second portion 12 is in a semi-cured state. Therefore, when the semiconductor chip 2 is pressed against the first portion 11 and the second portion 12, the thin film portion of the first portion 11 above the second portion 12 is extruded from the upper side of the second portion 12.

After the thin film portion of the first portion 11 is extruded, the semiconductor chip 2 comes into contact with the upper end of the second portion 12. Since the second portion 12 is in the semi-cured state but is not yet fully cured, when the semiconductor chip 2 is pressed against the second portion 12, an end surface thereof on the upper side is bonded to the semiconductor chip 2 in a state in which it conforms to the semiconductor chip 2. Thus, the second portion 12 connects the semiconductor chip 2 and the lead frame 3 in a sufficiently bonded state. Therefore, heat generated in the semiconductor chip 2 is efficiently dissipated to the lead frame 3 via the second portion 12.

To fully cure the molded first portion 11 and second portion 12, the semiconductor device 1 formed by mounting the semiconductor chip 2 on the adhesive layer 10 is heated at 200 to 250° C. in an oven, for example. Thus, the method for manufacturing the semiconductor device 1 is completed.

According to at least one embodiment described above, since the plurality of second portions 12 formed of the second material having a higher elastic modulus and a higher thermal conductivity than the first material, located inside the first portion 11, and in contact with and connected to the semiconductor chip 2 and the lead frame 3 are provided, the first portion 11 absorbs stress caused by the difference in linear expansion coefficient between the semiconductor chip 2 and the lead frame 3 during moisture absorption/reflow and temperature cycle tests, and curbs peeling, and thus it is possible to curb a decrease in the thermal conductivity.

According to at least one embodiment, since the plurality of second portions 12 are disposed in a lattice pattern at intervals when seen in the direction in which the semiconductor chip 2 and the lead frame 3 are arranged, heat generated in the semiconductor chip 2 can be dissipated to the lead frame 3 uniformly over a wide region on the semiconductor chip 2.

Further, according to at least one embodiment, since each of the plurality of second portions has a columnar shape that connects the semiconductor chip 2 and the lead frame 3, the semiconductor chip 2 and the lead frame 3 can be connected with a shortest distance, and heat dissipation from the semiconductor chip 2 to the lead frame 3 can be improved.

Further, according to at least one embodiment, since each of the plurality of second portions 12 has a cylindrical shape, when the first material is applied around the plurality of second portions 12 to form the first portion 11, the fluidity of the first material can be improved compared to when, for example, each of the second portions 12 has a prismatic shape with a rectangular cross section.

Further, according to at least one embodiment, since the total area of the plurality of second portions 12 in contact with the semiconductor chip 2 is ⅛ or more and ¼ or less of the area of the surface of the semiconductor chip 2 that faces the adhesive layer 10, it is possible to ensure the heat dissipation from the semiconductor chip 2 to the lead frame 3 and the expansion of the first portion 11 in accordance with the expansion of the lead frame 3.

Further, according to at least one embodiment, since each of the plurality of second portions 12 has a configuration containing metal particles, heat can be dissipated efficiently from the semiconductor chip 2 to the lead frame 3.

Further, according to at least one embodiment, since the forming of the second portion 12 includes applying the second material onto the lead frame 3 and then semi-curing the second material, when the first portion 11 is subsequently formed, deformation or the like of the second portion 12 can be curbed, and the second portion 12 can be connected to the semiconductor chip 2 and the lead frame 3 in a sufficiently bonded state, and thus heat generated in the semiconductor chip 2 can be efficiently dissipated to the lead frame 3 via the second portion 12.

According to at least one embodiment, since the first portion 11 and the second portion 12 are formed by screen printing, the first portion 11 and the second portion 12 can be easily formed, and production efficiency can be improved using the same printing method.

### Second Embodiment

A configuration of a semiconductor device 1 according to a second embodiment will be described below.

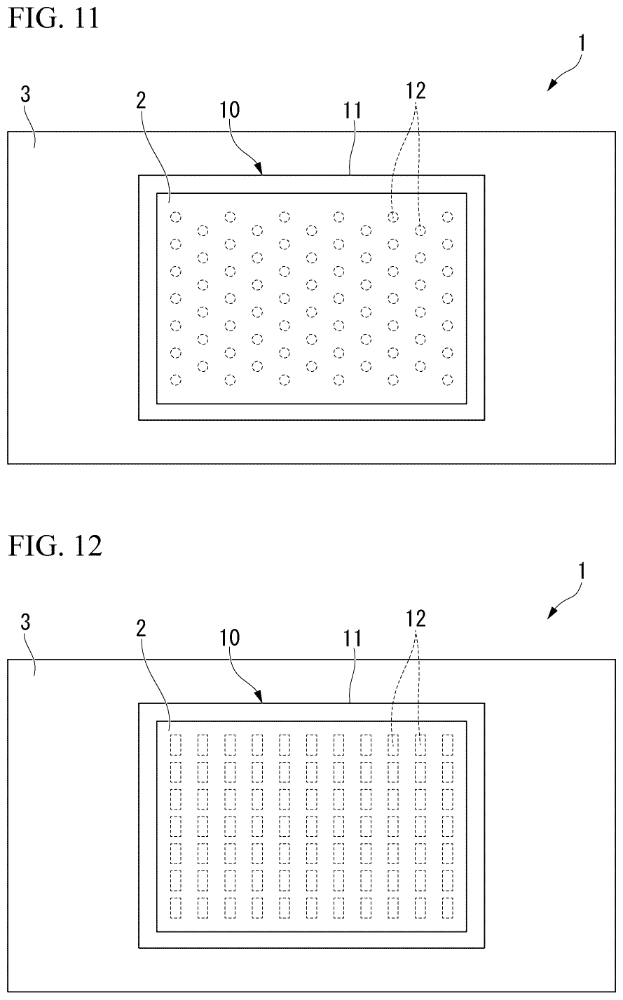

FIG. 11 is a plan view showing the semiconductor device 1 according to the second embodiment.

In the drawing, the same components as those of the semiconductor device 1 of the first embodiment shown in FIGS. 1 to 10 are designated by the same reference numerals, and the description thereof will be omitted.

The second embodiment differs from the first embodiment in the arrangement of the second portion 12.

As shown in FIG. 11, in plan view, a plurality of columns in which the second portions 12 are disposed at intervals in the longitudinal direction are disposed at intervals in the horizontal direction. In this embodiment, longitudinal positions of the second portions 12 in the columns laterally adjacent to each other are shifted by half a pitch. That is, the second portions 12 are disposed in a staggered manner in plan view when seen in the direction in which the semiconductor chips 2 and the lead frames 3 are arranged.

The other configuration is similar to that of the semiconductor device 1 in the first embodiment.

According to at least one the embodiment described above, in addition to obtaining the same action and effect as in the semiconductor device 1 according to the first embodiment described above, the maximum distance between the second portions 12 can be reduced by having the configuration in which the plurality of second portions 12 are disposed in a staggered pattern. Therefore, according to the embodiment, heat generated in the semiconductor chip 2 can be dissipated to the lead frame 3 more uniformly over a wide range on the semiconductor chip 2.

### Third Embodiment

A configuration of a semiconductor device 1 according to a third embodiment will be described below.

FIG. 12 is a plan view showing the semiconductor device 1 of the third embodiment.

In the drawing, the same components as those of the semiconductor device 1 of the first embodiment shown in FIGS. 1 to 10 are designated by the same reference numerals, and the description thereof will be omitted.

The third embodiment differs from the first embodiment in a configuration of the second portion 12.

As shown in FIG. 12, each of the plurality of second portions 12 has a prismatic shape with a rectangular cross section.

The other configuration is similar to that of the semiconductor device 1 in the first embodiment described above.

According to at least one embodiment described above, in addition to obtaining the same functions and effects as those of the semiconductor device 1 according to the first embodiment, since each of the plurality of second portions 12 has a prismatic shape with a rectangular cross section, the second portions 12 can be effectively disposed for the semiconductor chip 2 that is rectangular in plan view. Therefore, according to the embodiment, heat generated in the semiconductor chip 2 can be dissipated to the lead frame 3 more uniformly over a wide range on the semiconductor chip 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip;
a substrate configured to support the semiconductor chip; and
an adhesive layer disposed between the semiconductor chip and the substrate and configured to bond the semiconductor chip and the substrate,
wherein the adhesive layer has a first portion formed of a first material, and a plurality of second portions formed of a second material having a higher elastic modulus and a higher thermal conductivity than the first material, the second portions being located inside the first portion, each of the second portions being in contact with and connecting the semiconductor chip and the substrate.

2. The semiconductor device of claim 1, wherein the plurality of second portions are disposed in a lattice pattern at intervals from each other when seen in a direction in which the semiconductor chip and the substrate are arranged.

3. The semiconductor device of claim 1, wherein each of the plurality of second portions has a columnar shape that connects the semiconductor chip and the substrate.

4. The semiconductor device of claim 3, wherein each of the plurality of second portions has a cylindrical shape.

5. The semiconductor device of claim 1, wherein a total area of the plurality of second portions in contact with the semiconductor chip is ⅛ or more and ¼ or less of an area of a surface of the semiconductor chip that faces the adhesive layer.

6. The semiconductor device of claim 5, wherein each of the plurality of second portions contains metal particles.

7. A method for manufacturing a semiconductor device, comprising:
forming an adhesive layer on a substrate, the adhesive layer having a first portion formed of a first material and a plurality of second portions formed of a second material having a higher elastic modulus and a higher thermal conductivity than the first material; and
mounting a semiconductor chip on the adhesive layer on a side opposite to the substrate,
wherein the forming of the adhesive layer includes applying the second material to the substrate to form a plurality of the second portions in contact with the substrate, and applying the first material to the substrate to form the first portion with the plurality of second portions located therein and in contact with the substrate, and
the mounting of the semiconductor chip includes bringing the semiconductor chip into contact with the first portion and the second portions and connecting the semiconductor chip and the substrate via the first portion and the second portions.

8. The method for manufacturing a semiconductor device of claim 7, wherein the forming of the second portion includes semi-curing the second material after applying the second material to the substrate.

9. The method for manufacturing a semiconductor device of claim 7, wherein the plurality of second portions are disposed in a lattice pattern at intervals from each other when seen in a direction in which the semiconductor chip and the substrate are arranged.

10. The method for manufacturing a semiconductor device of claim 7, wherein the first portion and the second portions are formed by screen printing.

11. The method for manufacturing a semiconductor device of claim 7, wherein each of the plurality of second portions is formed into a columnar shape.

12. The method for manufacturing a semiconductor device of claim 11, wherein each of the plurality of second portions is formed into a cylindrical shape.
